(19) United States
(12) Patent Application Publication
(10) Pub. No.: US 2006/0063110 A1
(43) Pub. Date: Mar. 23, 2006

(54) Process for preparing light-sensitive lithographic printing plate and method for processing the same

(75) Inventors: Hideo Kiyoyama, Tokyo (JP); Yutaka Araki, Tokyo (JP); Takashi Miyazaki, Tokyo (JP); Akira Furukawa, Tokyo (JP); Kenji Hirata, Tokyo (JP)

Correspondence Address: BIRCH STEWART KOLASCH & BIRCH, PO BOX 747, FALLS CHURCH, VA, 22040-0747, US

(73) Assignee: MITSUBISHI PAPER MILLS LIMITED, Tokyo (JP)

(21) Appl. No.: 10/944,189

(22) Filed: Sep. 20, 2004

(51) Int. Cl. G03F 7/00

(52) U.S. Cl. 430/302

(57) ABSTRACT

There is disclosed a process for preparing a negative type light-sensitive lithographic printing plate having an aluminum plate as a support and a light-sensitive layer, provided on the support, containing a polymer, an ethylenically unsaturated compound, a photopolymerization initiator and a sensitizer having an absorption at a wavelength region of from visible light to infrared rays, which comprises subjecting the aluminum support after anodization treatment to a treatment in a solution containing potassium silicate and having a molar ratio of SiO₂/M₂O where M represents an alkali metal being in the range of 0.3 to 3.5.

### BACKGROUND OF THE INVENTION

1. Field of the Invention

This invention relates to a process for preparing a light-sensitive lithographic printing plate using an aluminum plate as a support and a method for processing the same.

2. Prior Art

A widely used type of lithographic printing plate has a light-sensitive coating film coated on an aluminum support. This coating film cures by exposure to light and the portion not exposed is dissolved by a developing treatment. This type of a plate is called to as a negative type printing plate. A lithographic printing plate utilizes surface properties of a pattern formed on the surface of the lithographic printing plate and a background portion having lipophilic property and hydrophilic property, respectively. When conducting lithographic printing, ink and damping water are simultaneously applied onto the printing surface of a printing press, and the ink is selectively transferred onto the pattern having lipophilic property. The ink transferred onto the pattern is then transferred to an intermediate material called to as a blanket and further transferred to a printing paper whereby printing is carried out.

Many researches have been conventionally done about light-sensitive composition for forming a relief image utilizing change in solubility by the photoreaction as mentioned above, and practically applicable materials have been provided. For example, in Japanese Patent Publications No. Sho. 49-34041 and No. Hei. 6-105353 and U.S. Pat. No. 5,153,095, etc., a light-sensitive composition mainly comprising a polymer having an ethylenically unsaturated bond at the side chain, a cross-linking agent and a photopolymerization initiator has been disclosed. Such a composition has a light-sensitive property to light having a short wavelength mainly at a ultraviolet rays region of 400 nm or shorter.

On the other hand, in recent years, it has been desired to develop a light-sensitive material having high sensitivity to visible rays accompanying with the progress of image forming techniques. For example, researches have been actively carried out on a light-sensitive material and a light-sensitive lithographic printing plate corresponding to an output machine using argon laser, helium-neon laser, red-color LED, etc.

Moreover, accompanying with the marked progress in semi-conductor laser, a near infrared laser light source having 700 nm to 1300 nm can be easily used whereby a light-sensitive material and a light-sensitive lithographic printing plate corresponding to said laser light has attracted attention.

As a photopolymerizable composition having a light-sensitive property at the above-mentioned visible rays to near infrared rays, there are disclosed a lithographic printing plate containing a radical polymerizable compound having an ethylenically unsaturated bond, a photosensitizing dye having an absorption peak at 400 to 500 nm and a polymerization initiator in Japanese Unexamined Patent Publication No. Hei. 9-134007; a combination of an organic boron anion and a dye in Japanese Unexamined Patent Publication No. 2000-98603; a combination of a dye and an s-triazine compound in Japanese Unexamined Patent Publication No. Hei. 6-43633; and a combination of a resol resin, a novolac resin, an infrared rays absorber and a photo-acid generator in Japanese Unexamined Patent Publication No. Hei. 7-20629.

In an output machine utilizing a semiconductor laser or YAG laser which emits near infrared region of 750 nm or more, a high output laser with an output power of a light source of several hundreds mW to several watts size is mounted, so that image formation with an extremely high energy can be realized. As a light-sensitive lithographic printing plate in comply with such a near infrared laser, there are disclosed negative type image forming methods, as disclosed in, for example, Japanese Unexamined Patent Publications No. Hei. 7-20629, No. Hei. 7-271029, No. Hei. 9-185160, No. Hei. 9-197671, No. Hei. 9-222731, No. Hei. 9-239945 and No. Hei. 10-142780, in which, in combination of a latent acid generator and a near infrared rays absorbing dye, decomposition of the latent acid generator utilizing heat generated by photo-thermal conversion and acid catalyst-thermal crosslinking utilizing an acid generating at a laser irradiation portion are used.

Also, as a system in which a photon mode recording which is an application of the conventional high sensitivity photo-polymer techniques is applied to near infrared rays, there are disclosed high sensitivity negative type recording materials, as disclosed in, for example, Japanese Unexamined Patent Publications No. 2000-122274, No. 2000-131833, No. 2000-181059 and No. 2000-194124, in a photopolymer system containing a photopolymerization initiator and an ethylenically unsaturated compound, that use various kinds of dyes that spectrally sensitize the photopolymerization initiator by near infrared rays.

Also, in Japanese Unexamined Patent Publications No. 2001-290271 and No. 2002-278066, there are disclosed light-sensitive compositions containing a polymer having an ethylenically unsaturated double bond at a side chain, a photopolymerization initiator and a near infrared rays sensitizing dye. As a developer to be used for such a composition, there are disclosed that a highly alkaline developer containing a silicate with a pH exceeding 12 as disclosed in Japanese Unexamined Patent Publications No. 2002-278083, No. 2002-278084 and No. 2002-278085.

On the other hand, it has been known that a surface of an anodized aluminum support has been subjected to silicate treatment. For example, it has been disclosed in U.S. Pat. No. 5,811,215, No. 5,282,952 and No. 6,740,468. Also, as a support of a negative type light-sensitive lithographic printing plate for near infrared rays laser, it has been disclosed to use an aluminum plate subjected to silicate treatment as disclosed in Japanese Unexamined Patent Publications No. 2001-272787 and No. 2003-114532.

The silicate treatment is a preferred treatment in an offset printing on the points that water-retaining property at a non-image portion makes good and occurrence of background stain is prevented. However, in a light-sensitive lithographic printing plate in which a photopolymerizable light-sensitive layer which is in comply with various kinds of lasers from visible light to near infrared rays is provided on an aluminum support as mentioned above, adhesiveness between the aluminum support and the light-sensitive layer becomes worse by the silicate treatment whereby the problem in which printing property (printing endurance) is lowered is often generated.

The above-mentioned Japanese Unexamined Patent Publications No. 2001-272787 and No. 2003-114532 each disclose an invention that an intermediate layer containing an aluminum compound or a silicone compound is provided to improve adhesiveness between a silicate film formed by a silicate treatment and a light-sensitive layer.

The conventional silicate treatment is generally carried out by using sodium silicate at a high temperature of 70° C. or higher. In such a silicate treatment using sodium silicate, potent adhesiveness between a light-sensitive layer and an aluminum plate of a light-sensitive lithographic printing plate intended by the present invention cannot be obtained.

Moreover, in place of subjecting the aluminum support to silicate treatment, the silicate treatment has been carried out at the time of development. As this time, a developer containing a silicate and having a pH of in excess of 12 is used. Such a high pH developer involves a problem that a pH thereof is decreased with a lapse of time due to absorption of carbon dioxide in air, so that a fresh developer shall be supplemented frequently to prevent from lowering in pH. Moreover, such a developer having a high pH is dangerous and high toxicity, so that care should be highly taken for handling, preservation and transportation.

### SUMMARY OF THE INVENTION

An object of the present invention is to provide a process for preparing a negative type light-sensitive lithographic printing plate in which printing endurance and stain resistance are improved. Another object of the present invention is to provide a light-sensitive lithographic printing plate capable of treating with a developer having a pH of 12 or less and a method for processing the same.

The above-mentioned objects of the present invention can be accomplished by a process for preparing a negative type light-sensitive lithographic printing plate having an aluminum plate as a support and a light-sensitive layer which is provided on the support and contains a polymer, an ethylenically unsaturated compound, a photopolymerization initiator and a sensitizer having an absorption at a wavelength region of from visible light to infrared rays, which comprises subjecting the aluminum support after anodization treatment to a treatment in a solution containing potassium silicate and having a molar ratio of SiO₂/M₂O where M represents an alkali metal being in the range of 0.3 to 3.5.

Moreover, a preferred developing method of the present invention is a developing method of a negative type light-sensitive lithographic printing plate, which comprises subjecting the lithographic printing plate according to Claim 1 after image exposure with laser beam to development with an aqueous developer having a pH of 10 to 12.

### BRIEF DESCRIPTION OF THE DRAWING

FIG. 1 is a scanning type electron microscopic photograph in which a surface state of the aluminum support obtained by the treatment of the present invention was photographed.

### DESCRIPTION OF THE PREFERRED EMBODIMENTS

In the following, the embodiments of the present invention are explained in detail.

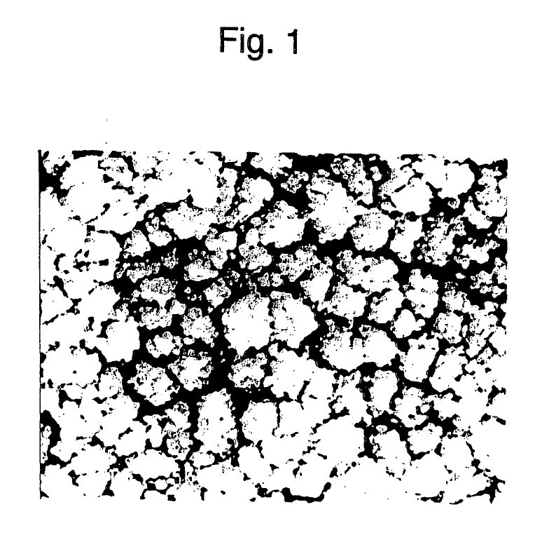

The treatment of the present invention using a solution containing potassium silicate is different from the conventional silicate treatment (i.e., a treatment to form a silicate film on an anodized aluminum plate by treating it with sodium silicate at a high temperature of 70° C. or higher), and can form minute projected structure on a surface of the aluminum support whereby hydrophilicity at a non-image portion can be improved while maintaining adhesiveness between a light-sensitive layer and the surface of the aluminum plate (see FIG. 1). In the processing solution of the present invention, if a molar ratio of SiO₂/M₂O becomes too little, corrosion at the surface of the aluminum support becomes significant to worse water-retaining property, while if it is too large, minute projected structure is not formed on the surface of the aluminum support whereby potent adhesiveness cannot be obtained.

By using the aluminum support subjected to the treatment of the present invention and a negative type light-sensitive layer in combination, potent adhesiveness can be obtained without providing any intermediate layer, etc.

The aluminum plate to be used as a support of the light-sensitive lithographic printing plate of the present invention comprises a metal mainly containing aluminum which is dimensionally stable and comprises aluminum or an aluminum alloy.

In the following explanation, various kinds of substrates comprising aluminum or an aluminum alloy mentioned above are called to as an aluminum plate. As a hetero element to be contained in the above-mentioned aluminum alloy, there may be mentioned silicon, iron, manganese, copper, magnesium, chromium, zinc, bismuth, nickel, titanium and the like, and the content of the hetero element in the aluminum alloy is 10% by weight or less. A content of copper is particularly preferably 0 to 0.05% by weight.

In the present invention, it is suitable to use a pure aluminum plate but it is difficult to produce a completely pure aluminum plate in view of the refining technology so that a small amount of the hetero element may be contained. As mentioned above, the aluminum plate to be used in the present invention is not specifically limited in the composition, and conventionally well known and widely been used materials including aluminum alloy plates such as JIS A1050, JIS A1100, JIS A3005, JIS A3004, International Registration Alloy 3103A and the like may be optionally employed. A method for producing the aluminum plate may be either of the continuous casting system or of the DC casting system, and an aluminum plate in which an intermediate annealing or uniform heating treatment in the DC casting system is omitted may be used. Also, an aluminum plate to which unevenness is applied by a laminating rolling or transfer, etc. at the final rolling may be used. A thickness of the aluminum plate to be used in the present invention is about 0.1 mm to about 0.6 mm. The thickness may be optionally changed according to a size of a printing machine, a size of a lithographic printing plate, or a request by a user.

The aluminum support for the lithographic printing plate of the present invention can be obtained by subjecting an anodization treatment and hydrophilic treatment to the above-mentioned aluminum plate. In the preparation process of the aluminum support, various steps other than the above anodization treatment and hydrophilic treatment may be contained.

The above aluminum plate is usually subjected to a sand grinding treatment to obtain a more preferred shape. As the sand grinding treatment, there may be used a mechanical sand grinding (a mechanical surface roughening treatment) as disclosed in Japanese Unexamined Patent Publication No. Sho. 56-28893, a chemical etching, an electrolysis grain, etc. Moreover, there may be used an electrochemical sand grinding method (an electrochemical surface roughening treatment, an electrolysis surface roughening treatment) in which a material is electrochemically sand grinded in a hydrochloric acid electrolytic solution or nitric acid electrolytic solution, and a mechanical sand grinding method (a mechanical surface roughening treatment) such as a wire brush grain method in which an aluminum surface is scratched with metallic wire, a ball grain method in which an aluminum surface is sand grinded with ground balls and a grinding agent, a brush grain method in which a surface is sand grinded with a Nylon brush and a grinding agent, etc. These sand grinding methods can be used singly or in combination. For example, there may be mentioned a combination of a mechanical surface roughening treatment by a Nylon brush and a grinding agent, and an electrolysis surface roughening treatment using a nitric acid electrolytic solution or a combination of a plural number of the electrolysis surface roughening treatments.

In the brush grain method, an average depth at the concave portions to the direction of a long wavelength component of the surface of the aluminum support can be controlled by optionally selecting respective conditions such as an average grain diameter and a maximum grain size of the particles to be used as a grinding agent, hair diameter, hair density and a pressure of the brush to be pressed, etc. The concave portions obtained by the brush grain method preferably have an average wavelength of 3 to 15 μm and an average depth of 0.3 to 1 μm.

The electrochemical surface roughening method preferably includes an electrochemical method in which sand grinding is carried out chemically in a hydrochloric acid electrolytic solution or nitric acid electrolytic solution. A current density thereof is preferably an electric amount at an anode of 50 to 400 C/dm². More specifically, it is preferably carried out in an electrolyte containing 0.1 to 50% by weight of hydrochloric acid or nitric acid at a temperature of 20 to 100° C. for 1 second to 30 minutes with a current density of 100 to 400 C/dm² with the use of a direct current or an alternating current. According to the electrolytic surface roughening treatment, it is easy to provide fine unevenness to the surface, so that it is suitable to improve adhesiveness between the light-sensitive layer and the aluminum support.

According to the electrochemical surface roughening treatment after the mechanical surface roughening treatment, crater or honeycomb shaped pits with an average diameter of 0.3 to 1.5 μm and an average depth of 0.05 to 0.4 μm can be formed on the surface of the aluminum plate with a surface areal ratio of 80 to 100%. When the electrochemical surface roughening treatment alone is carried out without carrying out the mechanical surface roughening treatment, it is preferred to make an average depth of the pits less than 0.3 μm. The pits provided have functions of preventing stain at the non-image portion of a printing plate and improving printing endurance. In the electrolytic surface roughening treatment, an electric amount necessary for providing a sufficient amount of pits to the surface, i.e. the product of a current and a time during which the current turns on is an important condition. It is preferred to form a sufficient amount of pits with a less amount of electricity in the point of saving energy. A surface roughness after the roughening treatment preferably has a mathematical average roughness (Ra) of 0.2 to 0.8 μm measured by a cutoff value of 0.8 mm and an evaluation length of 3.0 mm according to JIS B0601-1994.

To the aluminum plate thus subjected to the sand grinding treatment, a chemical etching treatment is further preferably carried out. As the chemical etching treatment, it has been known an etching with an acid or an etching with an alkali, and a chemical etching treatment using an alkali solution may be mentioned as a method which is particularly excellent in the point of etching efficiency.

The alkali agent to be suitably used in the present invention is not specifically limited, and there may be mentioned, for example, sodium hydroxide, sodium carbonate, sodium aluminate, sodium metasilicate, sodium phosphate, potassium hydroxide and lithium hydroxide. The conditions for the alkali etching treatment are so set that a dissolved amount of Al is 0.05 to 1.0 g/m². The other conditions are not specifically limited, and a concentration of the alkali is preferably 1 to 50% by weight, more preferably 5 to 30% by weight, and a temperature of the alkali is preferably 20 to 100° C., more preferably 30 to 50° C. The alkali etching treatment is not limited only by one method and a plural number of steps may be combined. In the present invention, the alkali etching treatment may be carried out after the mechanical surface roughening treatment and before the electrochemical surface roughening treatment. In this case, a dissolved amount of Al is preferably set to 0.05 to 30 g/m².

After subjecting to the alkali etching treatment, washing with an acid is carried out to remove stain (or smut) remained at the surface. As the acid to be used, there may be mentioned nitric acid, sulfuric acid, phosphoric acid, chromic acid, hydrofluoric acid and borofluoric acid. As the smut removing treatment method after the electrolysis surface roughening treatment, a method of contacting with sulfuric acid with a concentration of 15 to 65% by weight at a temperature of 50 to 90° C. is preferably mentioned as disclosed in Japanese Unexamined Patent Publication No. Sho. 53-12739.

When the chemical etching treatment is carried out with an acidic solution, the acid to be used for the acidic solution is not specifically limited, and, for example, sulfuric acid, nitric acid, hydrochloric acid, etc. are mentioned. A concentration of the acid solution is preferably 1 to 50% by weight. Also, a temperature of the acid solution is preferably 20 to 80° C.

To the thus treated aluminum plate as mentioned above, an anodization treatment is further carried out. The anodization treatment can be carried out with a method that has conventionally been carried out in this field of the art. More specifically, an anodized film can be formed on the surface of the aluminum plate when a direct current or an alternating current is passed through the aluminum plate in an aqueous or non-aqueous solution containing at least one of sulfuric acid, phosphoric acid, chromic acid, oxalic acid, sulfamic acid, benzenesulfonic acid, etc.

At this time, at least one of the components usually contained in the Al alloy plate, an electrode, tap water, subterranean water, etc. may be contained in the electrolyte. Moreover, the second and the third components may be added to the electrolyte. The second and the third components herein mentioned may include, for example, an ion of a metal such as Na, K. Mg, Li, Ca, Ti, Al, V, Cr, Mn, Fe, Co, Ni, Cu, Zn, etc.; a cation such as an ammonium ion; an anion such as a nitrate ion, a carbonate ion, a chloride ion, a phosphate ion, a fluoride ion, a sulfite ion, a titanate ion, a silicate ion, a borate ion, etc., with a concentration of 0 to about 1000 ppm in the electrolyte.

The conditions of the anodization treatment may vary depending on the electrolyte to be used and cannot be solely determined. The conditions are generally an electrolyte concentration of 1 to 80% by weight, a liquid temperature of −5 to 70° C., a current density of 0.5 to 60 A/dm², a voltage of 1 to 100 V and an electrolysis time of 10 to 200 seconds. Of these anodization treatment, it is particularly preferred to carry out the anodization treatment under high current density in a sulfuric acid electrolyte as disclosed in GB Patent No. 1,412,768.

In the present invention, an amount of the anodized film is preferably 1 to 10 g/m². If it is less than 1 g/m², scratch or flaw is likely generated on the plate, while if it exceeds 10 g/m², a great amount of electric power is required for production so that it is economically disadvantageous. An amount of the anodized film is more preferably 1.5 to 7 g/m², particularly preferably 2 to 5 g/m². After the surface roughening treatment, an alkali etching treatment may be carried out before the electrochemical surface roughening treatment. In this case, an amount of Al to be dissolved is preferably set to 0.05 to 30 g/m².

The aluminum plate to be used in the present invention is treated by a solution containing potassium silicate after anodization treatment. This solution contains potassium silicate and a molar ratio of SiO₂/M₂O (where M represents an alkali metal) is within the range of 0.3 to 3.5. Preferred molar ratio of SiO₂/M₂O is 0.5 to 3.0, more preferably 0.8 to 2.5, and further preferably 1.0 to 2.5.

M in the above mentioned SiO₂/M₂O means an alkali metal, and the solution of the present invention contains potassium silicate, so that at least potassium is contained as the alkali metal (M). As the alkali metal (M), sodium or lithium may be contained, but in the present invention, an amount of potassium is preferably 50 mol % or more, more preferably 70 mol % or more, particularly preferably 100 mol % based on the total amount of the alkali metal (M).

A concentration of the silicate in the solution is preferably within the range of 0.5 to 10% by weight, more preferably 0.8 to 8% by weight, particularly preferably 1 to 6% by weight in terms of SiO₂ in the solution.

To the solution, an alkali metal hydroxide such as sodium hydroxide, potassium hydroxide, lithium hydroxide and the like is preferably added. A concentration of the alkali metal hydroxide in the solution is preferably 0.5 to 5% by weight, more preferably 1 to 4% by weight. Of these alkali metal hydroxides, potassium hydroxide is particularly preferred, and a concentration of potassium hydroxide in the solution is preferably 0.5 to 5% by weight, more preferably 1 to 4% by weight. Also, a pH of the solution at 25° C. is preferably 12 or higher, more preferably in the range of 12 to 13.5, particularly preferably in the range of 12.3 to 13.3.

A temperature of the solution containing potassium silicate at the time of the treatment is generally 5 to 80° C., preferably 70° C. or lower, more preferably 65° C. or lower. A treatment time is, for example, preferably 1 to 60 seconds, particularly preferably 3 to 50 seconds when the aluminum plate is immersed in the treating solution.

After the treatment using the solution containing potassium silicate as mentioned above, washing treatment is carried out. The method of washing is not specifically limited, and may be mentioned, for example, a spraying method, a dipping method, etc. These methods may be carried out alone once or several times, or in combination of two or more methods. A time for washing is not specifically limited.

Also, in the present invention, after anodization treatment and before the treatment with the solution containing potassium silicate, it is preferred to carry out pore sealing treatment with vapor or hot water at 60° C. or higher. The pore sealing treatment by vapor or hot water can be carried out under the conditions conventionally employed. By using the pore sealing treatment and the treatment with the solution containing potassium silicate according to the present invention in combination, adhesiveness between the aluminum plate and the light-sensitive layer is further improved.

The light-sensitive lithographic printing plate of the present invention can be prepared by coating a light-sensitive layer on the above-mentioned aluminum plate and then drying. The light-sensitive layer of the present invention contains at least a polymer (a binder resin), an ethylenically unsaturated compound (a polymerizable compound), a photopolymerization initiator and a sensitizer having an absorption at a wavelength region of from visible light to infrared rays. The light-sensitive layer of the present invention is a negative type. The light-sensitive layer with a negative type cures at an exposed portion and dissolves out by a developing treatment at an unexposed portion.

The light-sensitive layer of the present invention can be exposed to various kinds of lasers having various wavelengths by adding thereto a sensitizer having an absorption at a wavelength region of from visible light to infrared rays. It is particularly preferred to correspond the light-sensitive layer to scanning exposure using laser beam at near infrared rays (wavelengths region of 750 to 1100 nm), whereby handling under light room (under a fluorescent light which cuts ultraviolet rays) is possible.

In the following, the light-sensitive layer of the present invention is explained in detail.

As a photopolymerization initiator to be used in the present invention, there may be mentioned an aromatic ketone, an aromatic onium salt compound, an organic peroxide, a hexaarylbiimidazole compound, a ketoxime ester compound, an azinium compound, an active ester compound, a trihaloalkyl-substituted compound and an organic borate. Of these, most preferably used is the organic borate and an organic boron anion constituting the organic borate is represented by the following formula (I): 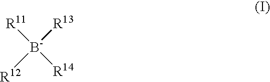
wherein R¹¹, R¹², R¹³ and R¹⁴ may be the same or different from each other, and each independently represents an alkyl group, an aryl group, an aralkyl group, an alkenyl group, an alkynyl group, a cyclo-alkyl group or a heterocyclic group. Of these, particularly preferred is that one of R¹¹, R¹², R¹³ and R¹⁴ represents an alkyl group and other three are aryl groups.

The above organic boron anion coexists with a cation which forms a salt therewith. As the cation in this case, there may be mentioned an alkali metal ion, an onium ion and a cationic sensitizing dye. As the onium ion, there may be mentioned an ammonium ion, a sulfonium ion, an iodonium ion and a phosphonium ion. When a salt of the alkali metal ion or the onium ion and the organic boron anion is used, if a sensitizing dye is separately added thereto, sensitivity at a wavelength region at which the dye absorbs light can be imparted. Also, when the organic boron anion is contained as a pair anion of the cationic sensitizing dye, sensitivity is imparted depending on an absorption wavelength of the sensitizing dye. In the latter case, it is preferred to use the organic boron anion as a pair anion of the alkali metal or the onium salt in combination.

As the organic borate to be used in the present invention, it is a salt containing the organic boron anion represented by the above-mentioned formula (I), and as the cation to form a salt, an alkali metal ion and an onium compound is preferably used. Particularly preferred examples of the onium salt with the organic boron anion is an ammonium salt such as tetraalkylammonium salt, etc., a sulfonium salt such as triarylsulfonium salt, etc., a phosphonium salt such as a triarylalkylphosphonium salt, etc. Particularly preferred examples of the organic borate are mentioned below.

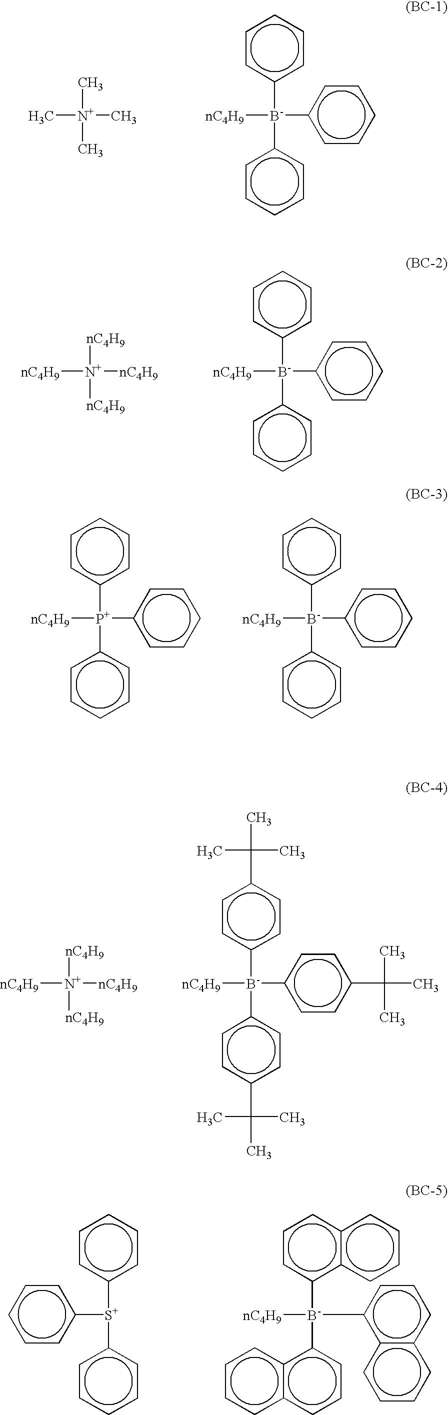

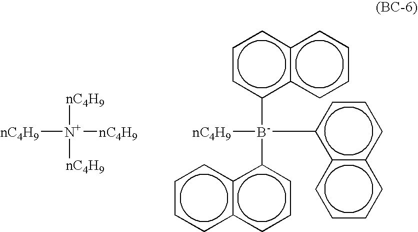

A content of the above-mentioned photopolymerization initiator is preferably 1 to 100 parts by weight, more preferably 1 to 40 parts by weight based on 100 parts by weight of the polymer.

As a preferred embodiment of the present invention, the organic borate is used in combination with a trihaloalkyl-substituted compound as photopolymerization initiators in the light-sensitive lithographic printing plate material. By using the trihaloalkyl-substituted compound in combination, preservability of the light-sensitive lithographic printing plate is good. The trihaloalkyl-substituted compound herein mentioned means a compound having at least one trihaloalkyl group such as a trichloromethyl group and a tribromomethyl group in the molecule. Preferred examples thereof may include an s-triazine derivative and an oxadiazole derivative in which said trihaloalkyl group binds to the nitrogen-containing heterocyclic group, or a trihaloalkylsulfonyl compound in which said trihaloalkyl group binds to an aromatic ring or a nitrogen-containing heterocyclic ring through a sulfonyl group.

Particularly preferred examples of the nitrogen-containing heterocyclic ring compound substituted by the trihaloalkyl group (T-1 to T-15) or the triahloalkylsulfonyl compound (BS-1 to BS-10) are mentioned below:

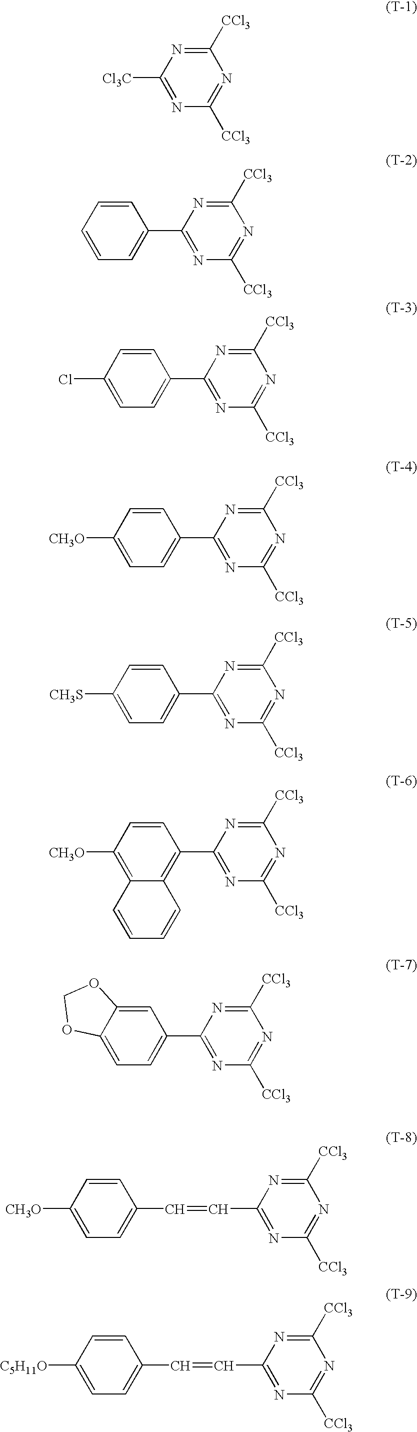

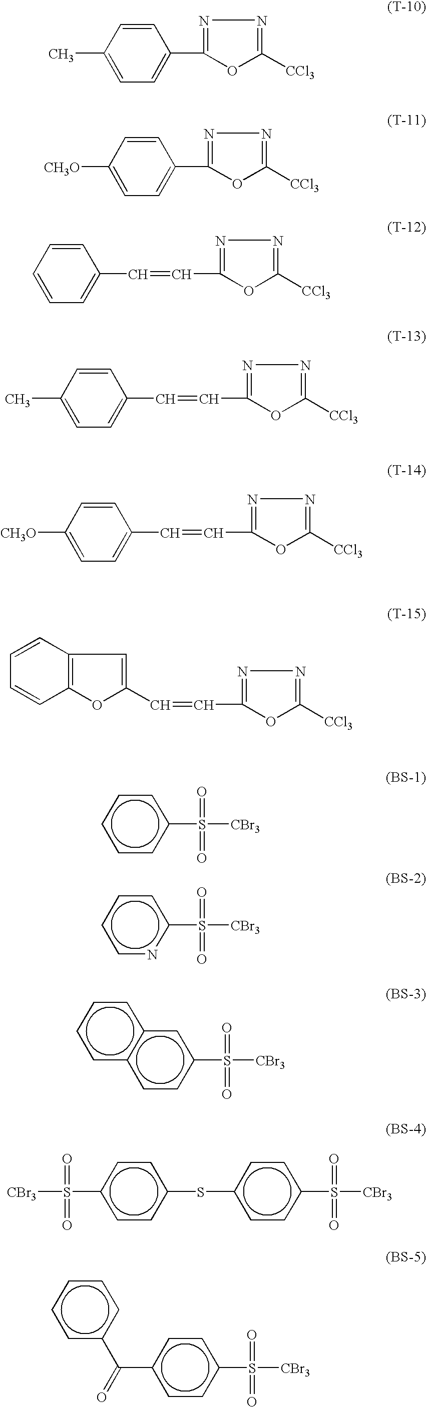

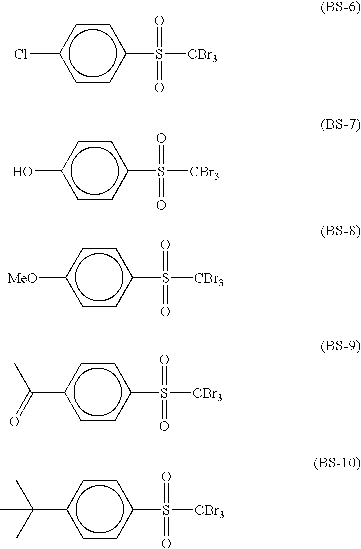

A content of the above-mentioned nitrogen-containing heterocyclic ring compound substituted by the trihaloalkyl group or the triahloalkylsulfonyl compound is preferably 1 to 100 pars by weight, more preferably 1 to 40 parts by weight based on 100 parts by weight of the polymer.

As a preferred embodiment of the present invention, the organic borate is preferably used in combination with a dye which sensitizes the salt in the light-sensitive lithographic printing plate material. The organic borate used at this time is a salt which does not show any sensitivity at the wavelength region from the visible light to the infrared light and firstly shows sensitivity to the light with such a wavelength region by the addition of the sensitizing dye.

The light-sensitive layer of the present invention preferably contains a sensitizer which has an absorption at a wavelength region from the visible light to the infrared light and can sensitizes the above-mentioned photoradical generator so that the composition can correspond to various light sources from the visible light to infrared light. As the sensitizing agent, various kinds of sensitizing dyes can be preferably used. Such sensitizers may include cyanine, phthalocyanine, merocyanine, coumarin, porphyrin, a spiro compound, ferrocene, fluorene, fulgide, imidazole, perylene, phenazine, phenothiazine, polyene, an azo compound, diphenylmethane, triphenylmethane, polymethyne acridine, ketocoumarin, quinacridone, indigo, styryl, a squarylium compound, a pyrilium compound, a thiopyrilium compound, etc., and further, compounds disclosed in EP 0 568 993 B, U.S. Pat. No. 4,508,811 and No. 5,227,227 may be used.

Specific examples of the sensitizing dye having an absorption at visible light region (360 to 700 nm) are mentioned below, but the present invention is not limited by them.

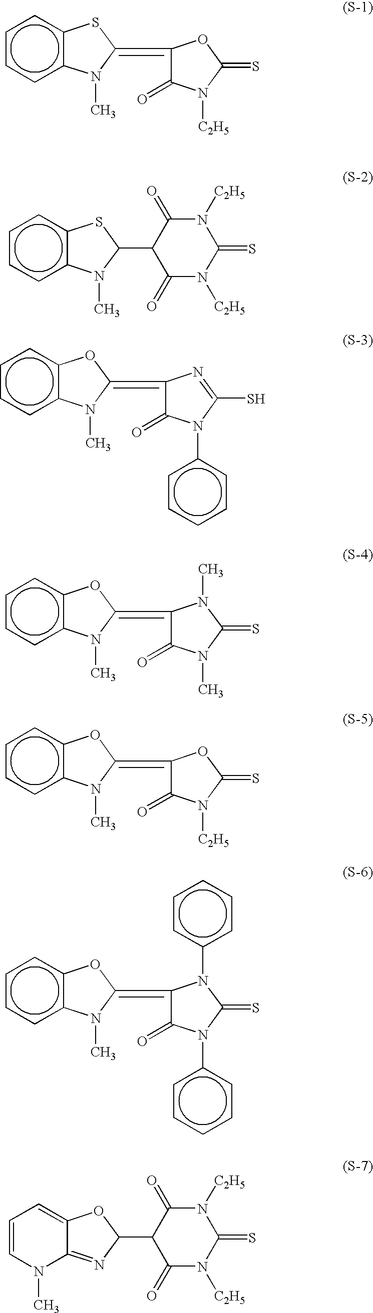

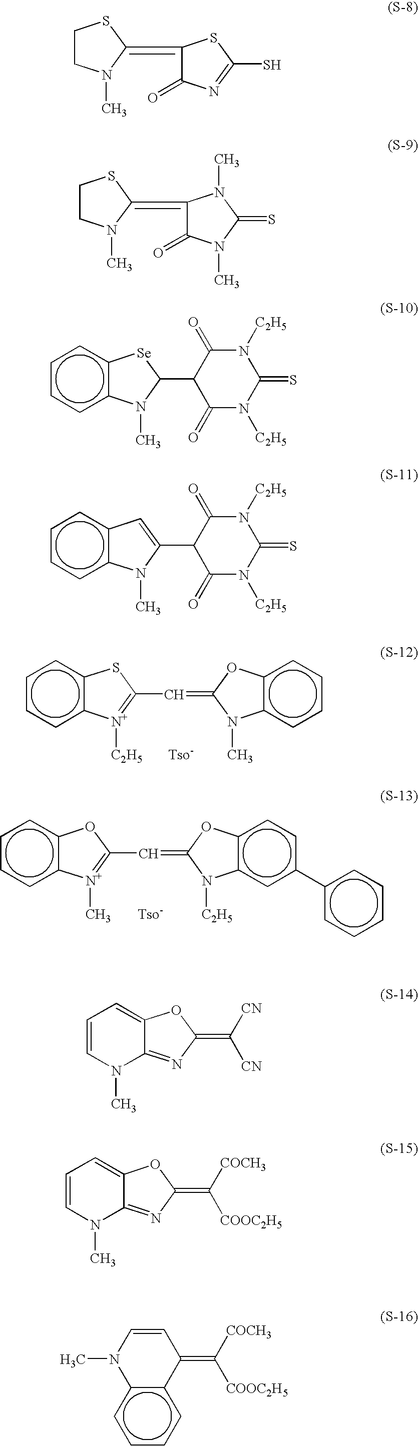

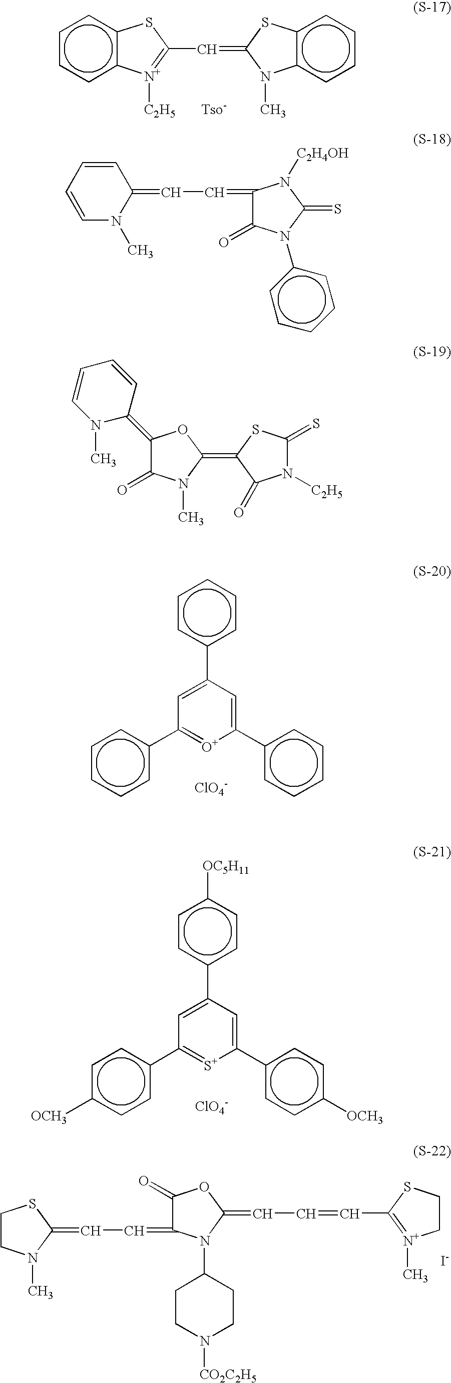

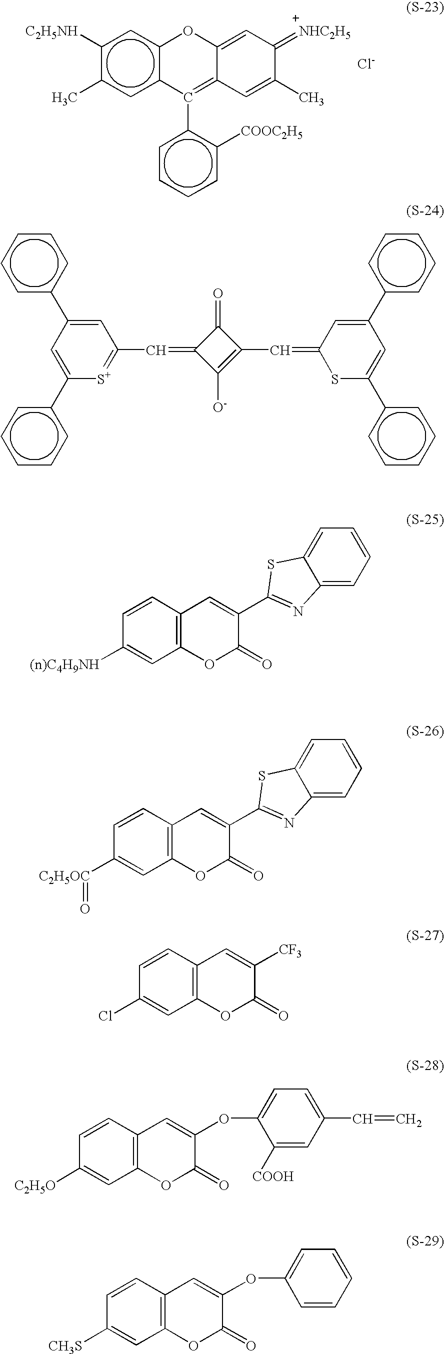

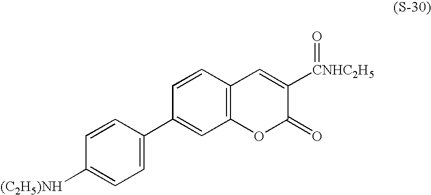

In recent years, an output machine mounted thereon a violet laser diode having an oscillation wavelength of 360 to 430 nm has been developed. This output machine has the maximum exposure energy dose of several tens μJ/cm² or so and a light-sensitive material to be used is required to have high sensitivity. In the present invention, it can be realized to use the lithographic printing plate of the present invention in this output machine by using the above-mentioned sensitizing dye in combination. Among the above-mentioned sensitizing dyes, the pyrilium compound or the thiopyrilium compound is preferred for the violet laser diode.

Also, the lithographic printing plate of the present invention can be extremely suitably used for light with near infrared rays, i.e., 700 nm or longer, further for scanning exposure using laser light with wavelength region of 750 to 1100 nm. Specific examples of sensitizing dyes to be used for sensitizing the composition to near infrared rays are shown below.

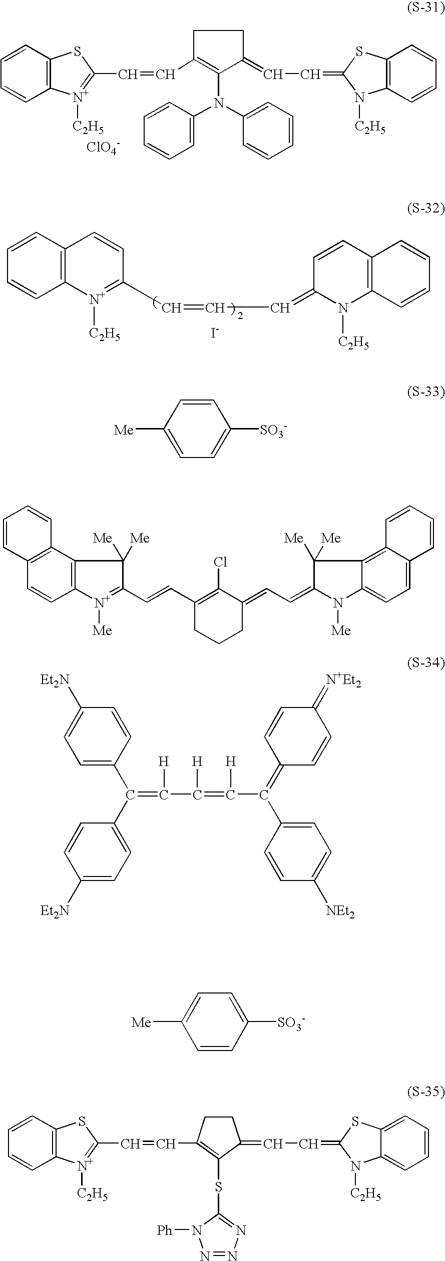

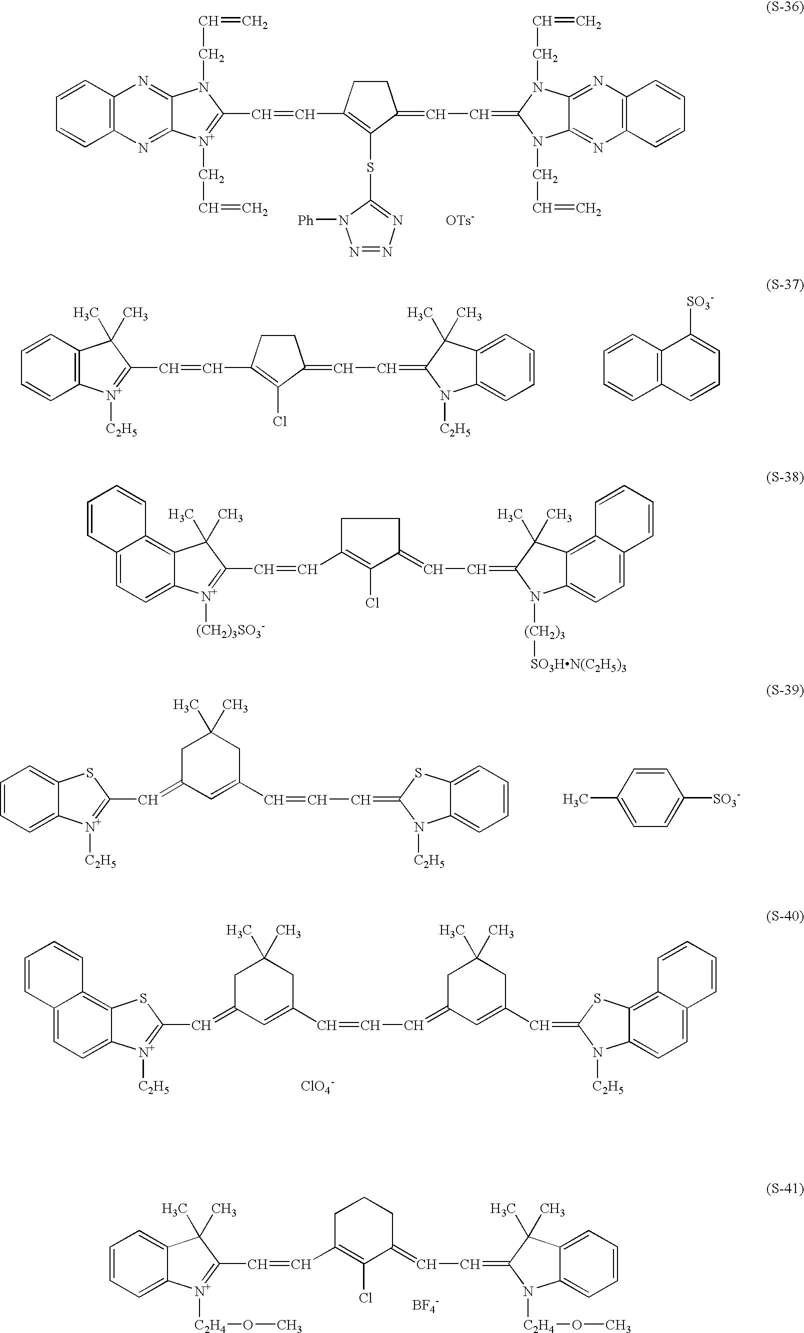

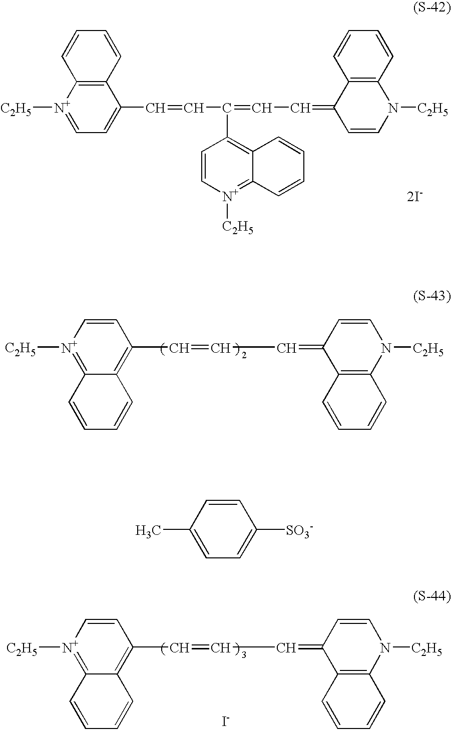

A pair anion of the exemplified sensitizing dyes as mentioned above is substituted for the above-mentioned organic boron anion can be used similarly in the present invention. An amount of the sensitizing dye is preferably 3 to 300 mg per 1 m² of the lithographic printing plate, more preferably 10 to 200 mg/m².

As the polymer (a binder resin) to be used in the present invention, an alkali-soluble polymer or a water-soluble polymer may be used, and an alkali-soluble polymer is particularly preferably used. The alkali-soluble polymer to be used in the present invention is a polymer which is capable of dissolving in or removable by an aqueous alkali solution, and preferably a polymer having a substituent(s) such as a hydroxyl group, a phenolic hydroxyl group, a carboxyl group, an ammonium salt group, etc. in the recurring unit constituting the polymer, particularly preferably used is a polymer having a carboxyl group.

As the above-mentioned particularly preferred alkali-soluble polymer having a carboxyl group, it is preferably various kinds of polymers comprising a copolymer, particularly preferably a polymer obtained by copolymerization of a monomer having a carboxyl group and other copolymerizable monomer. An amount of the monomer having a carboxyl group in the copolymer is preferably 5% by weight to 99% by weight. If the amount is less than the above range, the obtained copolymer tends to be not soluble in an aqueous alkali solution. The monomer containing a carboxyl group may include acrylic acid, methacrylic acid, 2-carboxyethyl acrylate, 2-carboxyethyl acrylate, crotonic acid, maleic acid, fumaric acid, monoalkyl maleate, monoalkyl fumarate, 4-carboxystyrene, etc.

As the particularly preferred alkali-soluble polymer in the present invention, a copolymer having the above-mentioned carboxyl group and having a polymerizable double bond at the side chain thereof is particularly preferred since it gives a light-sensitive composition with the highest sensitivity. Examples of such a polymer having a double bond at the side chain may include various polymers as disclosed in, for example, Japanese Patent Publications No. Sho. 49-34041, No. Hei. 6-105353 and 2000-187322. Examples of the polymers to be preferably used in the present invention are mentioned below. In the formulae, the numerals mean “% by weight” of the respective recurring units in the total copolymer composition as 100% by weight.

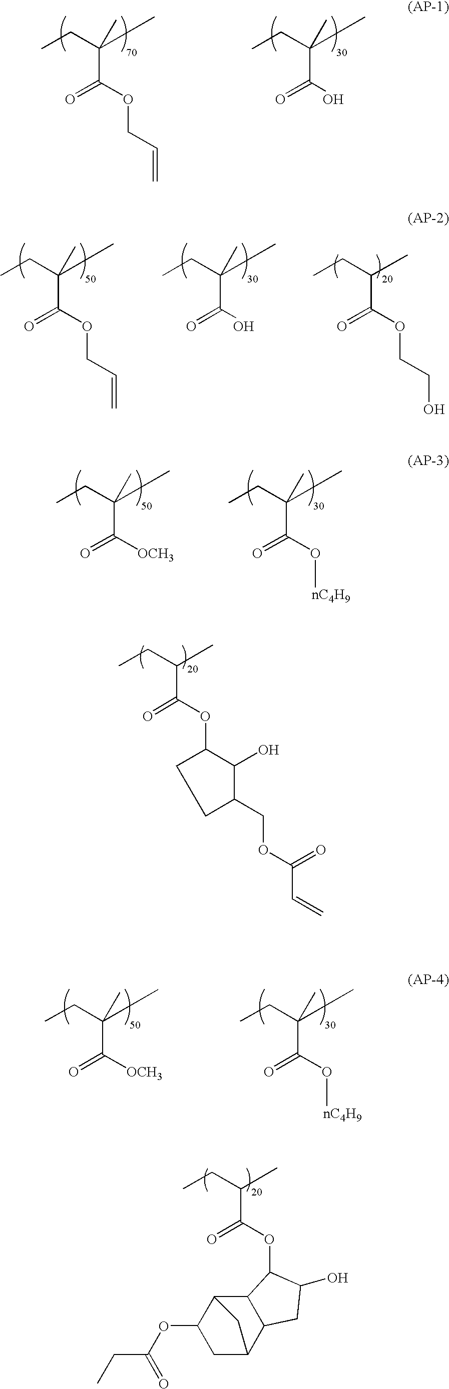

More preferred examples of the above-mentioned polymers having a polymerizable double bond at the side chain may include those having a specific structure mentioned below as the polymerizable double bond portion, since it gives a particularly higher sensitivity and is difficultly affected by oxygen, and no over layer to protect from oxygen is required. 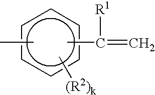
wherein R¹ represents a hydrogen atom or a methyl group, R² represents an optional atom or group other than a hydrogen atom, which is capable of substituting, and k is an integer of 0 to 4.

The polymer having the substituent shown by the above-mentioned formula at the side chain is a polymer in which the above substituent is directly or indirectly bound through a linking group. The linking group is not specifically limited and an optional group or atom, or integrated group of the group and atom may be mentioned. A polymer having the substituent mentioned above at the side chain is more specifically a polymer having the group represented by the following formula (II) at the side chain. 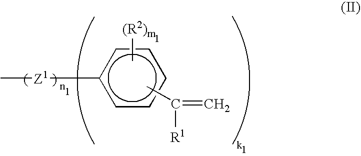
wherein Z¹ represents a linking group, n₁ is an integer of 0 or 1, m₁ is an integer of 0 to 4, k₁ is an integer of 1 to 4 and R¹ and R² have the same meanings as defined above.

The compound of the formula (II) is explained in more detail below. As the linking group of Z¹, there may be mentioned, for example, an oxygen atom, a sulfur atom, an alkylene group, an alkenylene group, an arylene group, —N(R³)—, —C(O)—O—, —C(R⁴)═N—, —C(O)—, a sulfonyl group, a heterocyclic group and a group represented by the following formula, each of which may be alone or a complex group of two or more of the above. Here, R³ and R⁴ each represent a hydrogen atom, an alkyl group or an aryl group. Moreover, with the above-mentioned linking groups, at least one of an alkyl group, an aryl group and a halogen atom may be substituted.

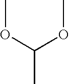

As the above-mentioned heterocyclic group, there may be mentioned, for example, a nitrogen-containing heterocyclic ring such as a pyrrole ring, a pyrazole ring, an imidazole ring, a triazole ring, a tetrazole ring, an isoxazole ring, an oxazole ring, an oxadiazole ring, an isothiazole ring, a thiazole ring, a thiadiazole ring, a thiatriazole ring, an indole ring, an indazole ring, a benzimidazole ring, a benzotriazole ring, a benzoxazole ring, a benzothiazole ring, a benzoselenazole ring, a benzothiadiazole ring, a pyridine ring, a pyridazine ring, a pyrimidine ring, a pyrazine ring, a triazine ring, a quinoline ring and a quinoxaline ring; and a furan ring and a thiophene ring; each of which may be substituted by at least one substituent.

Preferred examples of the group represented by the formula (II) are shown below, but the present invention is not limited by these.

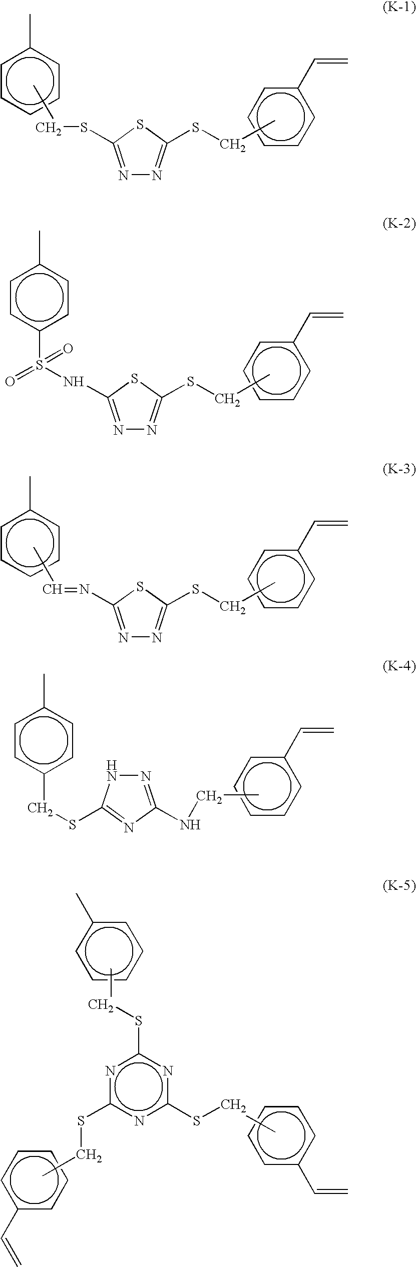

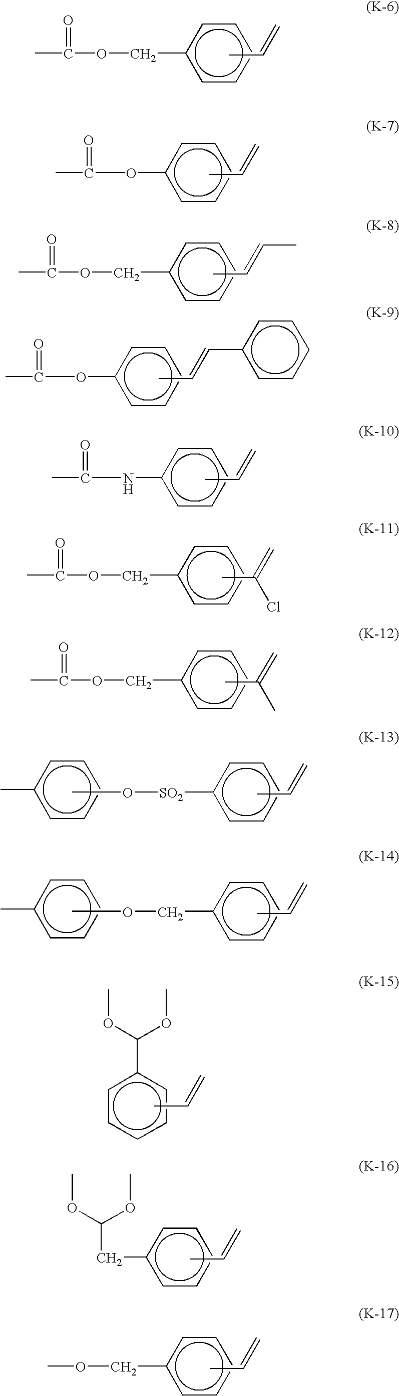

As the linking group in the above-mentioned formula (II), those containing a heterocyclic ring are preferred and those in which k₁ is 1 or 2 are also preferred.

As the polymer having the polymerizable double bond at a side chain shown by the above-mentioned various examples, it is preferred to have solubility in an aqueous alkaline solution, and particularly preferably a polymer containing a monomer having a carboxyl group as a copolymerizable component. In this case, as a ratio of the monomer having a double bond represented by the formula (II) in the copolymer composition, it is preferred to be 1% by weight to 95% by weight, more preferably 5 to 90% by weight, particularly preferably in the range of 10 to 90% by weight based on the total 100% by weight of the copolymer. If an amount of the group represented by the formula (II) is less than 1% by weight, the effect of incorporating the group cannot be admitted in some cases, while if it exceeds 95% by weight, the copolymer does not dissolve in an aqueous alkaline solution in some cases. Moreover, it is preferred to contain the monomer having a carboxyl group in the copolymer in an amount of 5% by weight to 99% by weight, more preferably in the range of 10 to 90% by weight based on the total weight of the copolymer. If an amount of the monomer is less than 1% by weight, the copolymer does not dissolve in an aqueous alkaline solution in some cases.

As the monomer having a carboxyl group mentioned above, there may be exemplified by, for example, acrylic acid, methacrylic acid, 2-carboxyethyl acrylate, 2-carboxyethyl methacrylate, crotonic acid, maleic acid, fumaric acid, monoalkyl maleate, monoalkyl fumarate, 4-carboxystyrene, etc. as mentioned above.

It is also possible to prepare a copolymer by incorporating a monomer other than the monomer having a carboxyl group in the copolymer to form a multi-component copolymer. As such a monomer to be incorporated into the copolymer, there may be mentioned, for example, a styrene derivative such as styrene, 4-methylstyrene, 4-hydroxystyrene, 4-acetoxystyrene, 4-carboxystyrene, 4-aminostyrene, chloromethylstyrene, 4-methoxystyrene, etc.; alkyl methacrylate such as methyl methacrylate, ethyl methacrylate, butyl methacrylate, hexyl methacrylate, 2-ethylhexyl methacrylate, cyclohexyl methacrylate, dodecyl methacrylate, etc.; aryl methacrylate or aralkyl methacrylate such as phenyl methacrylate, benzyl methacrylate, etc.; a methacrylic acid ester having a hydroxyalkyl group such as 2-hydroxyethyl methacrylate, 2-hydroxypropyl methacrylate, etc.; a methacrylic acid ester having an alkyleneoxy group such as methacrylic acid methoxydiethylene glycol monoester, methacrylic acid methoxypolyethylene glycol monoester, methacrylic acid polypropylene glycol monoester, etc.; methacrylate having an amino group such as 2-dimethylaminoethyl methacrylate, 2-diethylaminoethyl methacrylate, etc.; or acrylates corresponding to the above-mentioned methacrylates; a monomer having a phosphate group such as vinyl phosphonic acid, etc.; a monomer having an amino group such as allyl amine, diallyl amine, etc.; a monomer having a sulfonic acid group such as vinylsulfonic acid or a salt thereof, allylsulfonic acid or a salt thereof, methallylsulfonic acid or a salt thereof, styrenesulfonic acid or a salt thereof, 2-acrylamide-2-methylpropanesulfonic acid or a salt thereof, etc.; a monomer having a nitrogen-containing heterocyclic ring such as 4-vinylpyrrolidine, 2-vinylpyrrolidine, N-vinylimidazole, N-vinylcarbazole, etc.; a monomer having a quaternary ammonium salt group such as 4-vinyl benzyltrimethyl ammonium chloride, acryloyloxyethyltrimethyl ammonium chloride, methacryloyloxyethyltrimethyl ammonium chloride, a quaternized product of dimethylaminopropyl acrylamide by methyl chloride, a quaternized product of N-vinylimidazole by methyl chloride, 4-vinylbenzylpyridinium chloride, etc.; acrylonitrile, methacrylonitrile, etc.; an acrylamide or methacrylamide derivative such as acrylamide, methacrylamide, dimethylacrylamide, diethylacrylamide, N-isopropylacrylamide, diacetoneacrylamide, N-methylolacrylamide, N-methoxyethylacrylamide, 4-hydroxyphenylacrylamide, etc.; phenylmaleimide, hydroxyphenylmaleimide; a vinyl ester such as vinyl acetate, vinyl chloroacetate, vinyl propionate, vinyl butyrate, vinyl stearate, vinyl benzoate, etc.; a vinyl ether such as methyl vinyl ether, butyl vinyl ether, etc.; and other monomers such as N-vinylpyrrolidone, acryloylmorpholine, tetrahydrofurfuryl methacrylate, vinyl chloride, vinylidene chloride, allyl alcohol, vinyl trimethoxysilane, glycidyl methacrylate, and the like. As a ratio of these monomers having no carboxyl group in the copolymer composition, they can be optionally incorporated into the composition with any ratio so long as the ratios of the group represented by the formula (II) and the monomer having a carboxyl group are maintained in preferred ranges.

The molecular weight of the above-mentioned copolymer is preferably within the range of 1,000 to 1,000,000, more preferably 10,000 to 300,000 in terms of a weight average molecular weight (Mw).

A ratio of the polymer of the present invention in the light-sensitive layer is preferably within the range of 10 parts by weight to 80 parts by weight, more preferably 20 parts by weight to 80 parts by weight based on 100 parts by weight of the total components constituting the light-sensitive layer.

Examples of the polymer having the group represented by the formula (II) according to the present invention are shown below. In the formulae, the numeral means % by weight of the respective recurring units in the copolymer based on the total weight as 100% by weight.

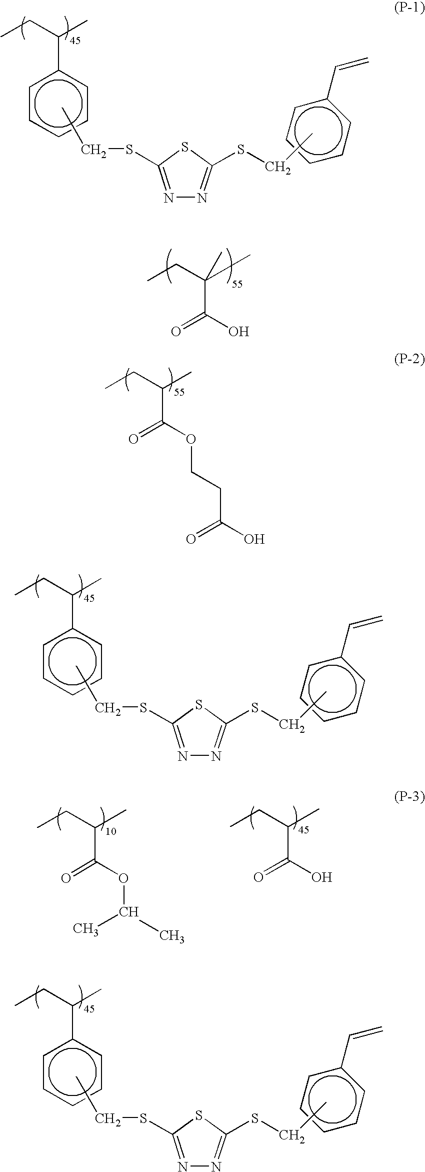

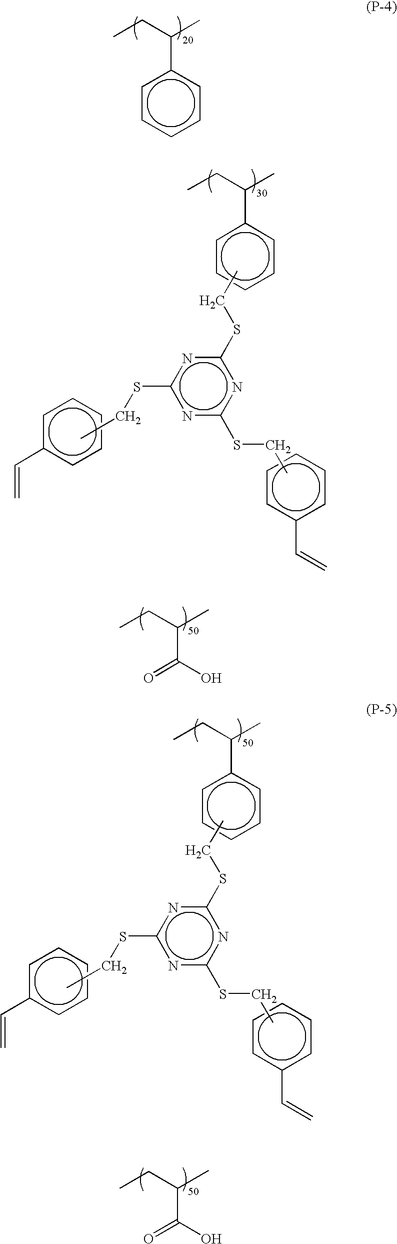

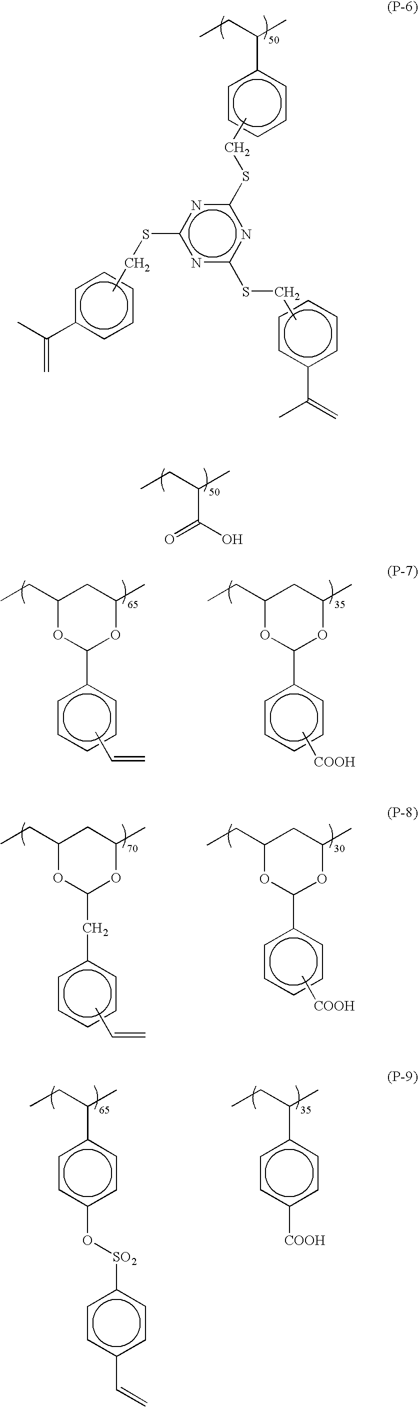

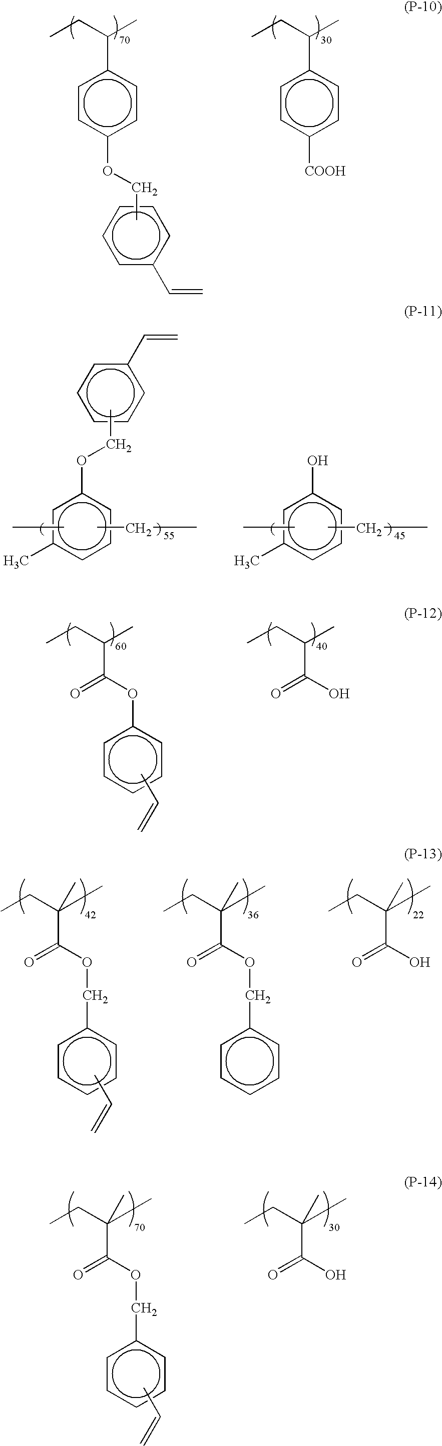

The light-sensitive layer of the present invention contains an ethylenically unsaturated compound. The compound is a monomer or an oligomer having two or more ethylenically unsaturated double bonds. A molecular weight of such a monomer or oligomer is 10,000 or less, preferably 5,000 or less. As the compound, there may be mentioned a compound having two or more ethylenically unsaturated double bonds such as an acryloyl group, a methacryloyl group, a vinylphenyl group, etc.

As the monomer or oligomer having an acryloyl group or a methacryloyl group as the ethylenically unsaturated double bonds, there may be mentioned, for example, 4-butanediol di(meth)acrylate, 1,6-hexanediol di(meth)acrylate, neopentyl glycol di(meth)acrylate, tetraethylene glycol di(meth)acrylate, trisacryloyloxyethyl isocyanurate, tripropylene glycol di(meth)acrylate, ethylene glycol glycerol tri(meth)acrylate, glycerolepoxy tri(meth)-acrylate, trimethylolpropane tri(meth)acrylate, trimethylolethane tri(meth)acrylate, pentaerythritol tri(meth)acrylate, pentaerythritol tetra(meth)acrylate, dipentaerythritol tri(meth)acrylate, dipentaerythritol tetra(meth)acrylate, dipentaerythritol penta(meth)acrylate, dipentaerythritol hexa(meth)acrylate, pyrogallol triacrylate, etc.

The monomer or oligomer having a vinylphenyl group as the ethylenically unsaturated double bonds may be representatively mentioned by the following formula: 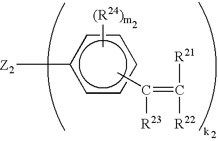
wherein Z₂ represents a linking group; R²¹, R²² and R²³ each represent a hydrogen atom, a halogen atom, a carboxyl group, a sulfo group, a nitro group, a cyano group, an amide group, an amino group, an alkyl group, an aryl group, an aryloxy group, etc., and each of these groups may be substituted by an alkyl group, an amino group, an aryl group, an alkenyl group, a carboxyl group, a sulfo group, a hydroxy group, etc.; R²⁴ represents a substitutable group or atom; m₂ is an integer of 0 to 4; and k₂ is an integer of 2 or more.

The compound of the above formula is explained in detail below. As the linking group Z₂, there may be mentioned an oxygen atom, a sulfur atom, an alkylene group, an alkenylene group, an arylene group, —N(R⁵)—, —C(O)—O—, —C(R⁶)═N—, —C(O)—, a sulfonyl group, a heterocyclic ring group, or at least one of the above are combined group. Here, R⁵ and R⁶ each represent a hydrogen atom, an alkyl group, an aryl group, etc. Moreover, to the above-mentioned linking groups, an alkyl group, an aryl group, a halogen atom, etc. may be substituted.

As the above-mentioned heterocyclic group, there may be mentioned, for example, a nitrogen-containing heterocyclic ring such as a pyrrole ring, a pyrazole ring, an imidazole ring, a triazole ring, a tetrazole ring, an isoxazole ring, an oxazole ring, an oxadiazole ring, an isothiazole ring, a thiazole ring, a thiadiazole ring, a thiatriazole ring, an indole ring, an indazole ring, a benzimidazole ring, a benzotriazole ring, a benzoxazole ring, a benzothiazole ring, a benzoselenazole ring, a benzothiadiazole ring, a pyridine ring, a pyridazine ring, a pyrimidine ring, a pyrazine ring, a triazine ring, a quinoline ring and a quinoxaline ring; and a furan ring and a thiophene ring; each of which may be substituted by at least one substituent.

Of the compounds represented by the above formula, there are preferred compounds. That is, preferred are compounds in which R²¹ and R²² are hydrogen atoms, R is a hydrogen atom or a lower alkyl group having 4 or less carbon atoms (a methyl group, an ethyl group, etc.), and k₂ is 2 to 10. In the following, specific examples thereof are shown, but the present invention is not limited by these compounds.

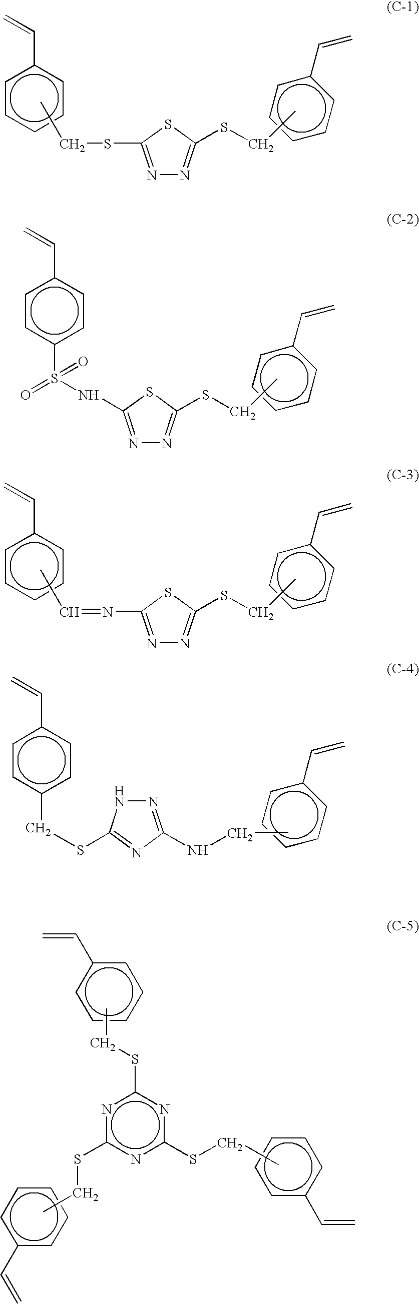

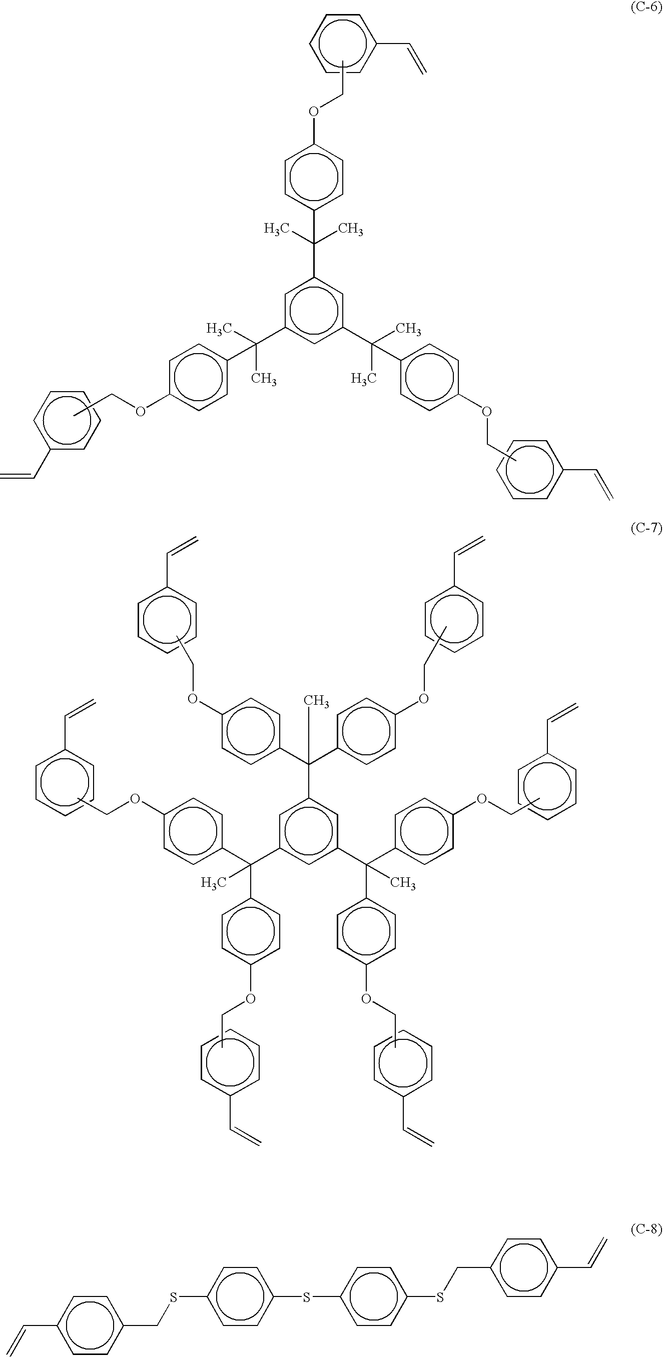

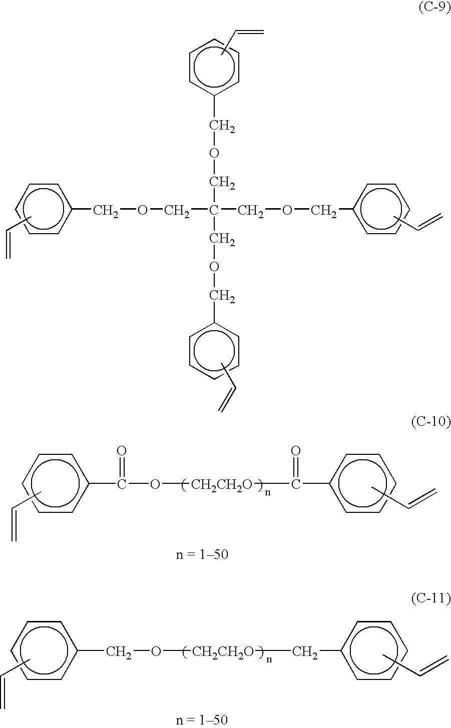

A content of the ethylenically unsaturated compound is preferably in the range of 1 to 100% by weight, more preferably in the range of 5 to 50% by weight based on the amount of the polymer.

The light-sensitive layer of the present invention further preferably contains a compound having an urethane bond and an ethylenically unsaturated bond (hereinafter referred to as “an urethane compound”). By adding such an urethane compound, dissolution property at the non-image portion of the light-sensitive layer is improved and background stain at the non-image portion can be further improved. The urethane compound to be used in the present invention has at least one urethane bond represented by the following formula in the molecule. Also, as the ethylenically unsaturated bond, there may be mentioned an acryloyl group or a methacryloyl group, and a compound having two or more ethylenically unsaturated bonds is preferably used. Moreover, a compound having two or more urethane bonds and three or more ethylenically unsaturated bonds is more preferably used.

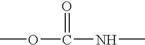

Specific examples of the above-mentioned urethane compound are mentioned below.

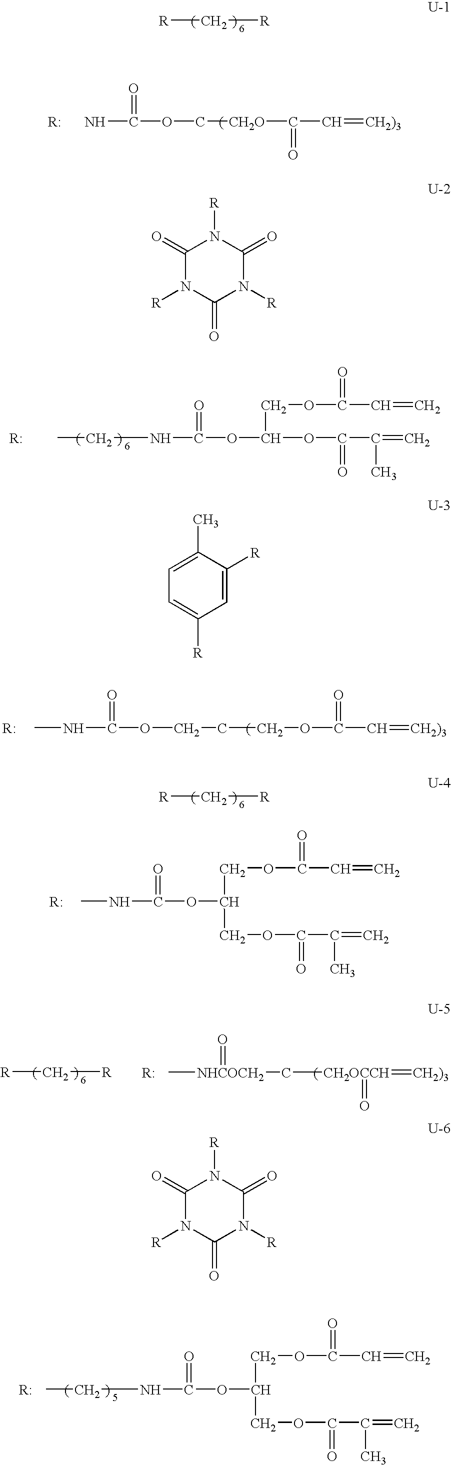

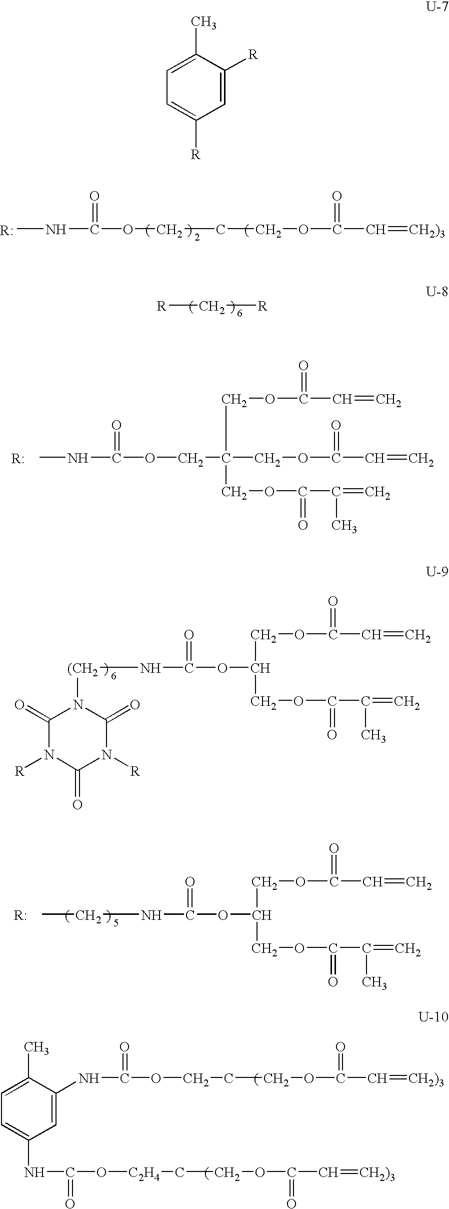

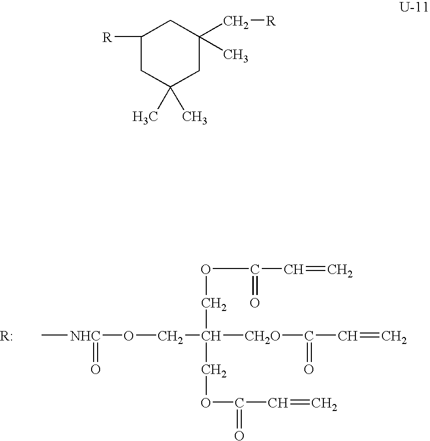

A content of the urethane compound is preferably in the range of 5 to 60% by weight, more preferably in the range of 10 to 50% by weight based on the amount of the polymer.

The light-sensitive layer of the present invention may preferably contain other components than those as mentioned above for the various purposes. For example, various kinds of polymerization inhibitors may be preferably added. As the polymerization inhibitors in this case, there may be preferably used various kinds of compounds having a phenolic hydroxyl group such as hydroquinones, chatechols, naphthols, cresols, etc., or quinone compounds, particularly preferably hydroquinone. An amount of the polymerization inhibitor in this case is preferably in the range of 0.1 to 10 parts by weight based on 100 parts by weight of the polymer.

As an element(s) to constitute the lithographic printing plate, various kinds of dyes or pigments may be preferably added for the purpose of heightening recognizability with eyes of image portion, or inorganic fine particles or organic fine particles may be added for the purpose of preventing from blocking of the light-sensitive composition.

As the above-mentioned pigments, there may be mentioned, for example, a black pigment, a yellow pigment, an orange pigment, a brown pigment, a red pigment, a purple pigment, a blue pigment, a green pigment, a fluorescent pigment, a metallic powder pigment, a polymer binding dye, etc. More specifically, there may be mentioned an insoluble azo pigment, an azo lake pigment, a condensed azo pigment, a chelate azo pigment, a phthalocyanine pigment, an anthraxquinone pigment, perylene and a perylene pigment, a thioindigo type pigment, a quinacridone pigment, a dioxazine pigment, an isoindolinone pigment, a quinophthalone pigment, a dye lake pigment, an azine pigment, a nitroso pigment, a nitro pigment, a natural pigment, a fluorescent pigment, an inorganic pigment, carbon black, etc.

These pigments may be used without carrying out the surface treatment, or may be used after carrying out the surface treatment. In the surface treatment method, there may be mentioned a method in which a resin or wax is subjected to surface coating, a method of adhering a surfactant, a method of binding a reactive substance (for example, a silane coupling agent, an epoxy compound, polyisocyanate, etc.) onto the surface of the pigment, and the like. The above-mentioned surface treatment methods are described in “Characteristics and Application of Metallic Soap” (published by Saiwai Shobo, Japan), “Printing Ink Technology” (published by CMC Publishing, 1984, Japan), and “Latest Pigment Application Technology (published by CMC Publishing, 1986, Japan).

A particle size of the above-mentioned pigment is preferably in the range of 0.01 to 10 μm, more preferably 0.05 to 1 μm, particularly preferably 0.1 to 1 μm. If the particle size of the pigment is less than 0.01 μm, it is not preferred in the point of stability of the dispersed materials in the coating solution for the light-sensitive layer, while if it exceeds 10 μm, it is not preferred in the point of uniformity of the light-sensitive layer.

As a method for dispersing the above-mentioned pigments, conventionally known dispersing techniques used for ink production or toner production may be used. As a dispersing machine, there may be mentioned, for example, an ultrasonic wave dispersing machine, a sand mill, an attritor, a pearl mill, a super mill, an inpellar, a disperser, a KD mill, a colloid mill, a dynatron, a three-roll mill, a pressure kneader, etc. Details are described in “Latest Pigment Application Technology (published by CMC Publishing, 1986, Japan).

A thickness of the light-sensitive layer itself to be used as a lithographic printing plate is preferably in the range of 0.5 μm to 10 μm with a dried thickness on the support, extremely preferably in the range of 1 μm to 5 μm for the purpose of markedly improving printing endurance. The light-sensitive layer may be provided on the support by using a conventionally known coating system, and dried.

For using a material having the light-sensitive layer formed on the support as mentioned above as a printing plate, a laser-beam scanning exposure is preferably carried out. By this exposure, the exposed portion is cross-linked so that its solubility to an alkali developer is lowered, and the non-exposed portion is dissolved out by the alkali developer to form a pattern.

The light-sensitive lithographic printing plate of the present invention has high printing endurance and does not generate any background stain at a non-image portion even when it is developed with a developer having a pH of 12 or less. A pH of the developer to be preferably used in the present invention is 10 to 12, more preferably 11 to 11.8. The pH of the developer is a pH at 25° C. As an alkaline compound to adjust the pH of the developer in the range of 10 to 12, there may be mentioned an alkali metal hydroxide such as sodium hydroxide, potassium hydroxide, etc., a tetraalkyl ammonium hydroxide such as tetramethyl ammonium hydroxide, tetrabutyl ammonium hydroxide, etc., an alkanolamine such as monoethanolamine, diethanolamine, triethanolamine, N-methylethanolamine, N-ethylethanolamine, etc. Of these, an alkanolamine is particularly preferred. A content of the alkanolamine is preferably 5 to 100 g, particularly preferably 10 to 60 g per liter of the developer.

The developer further preferably contains an anionic surfactant whereby dissolution property is further improved. Such an anionic surfactant may include a higher fatty acid sulfate, an alkylnaphthalene sulfonate, an alkylbenzene sulfonate, a dialkylsulfosuccinate, etc., and of these, an alkylnaphthalene sulfonate is particularly preferred. A content of the anionic surfactant is preferably 1 to 50 g, particularly preferably 3 to 30 g per liter of the developer.

To the developer may be further added a buffer such as phosphorus acid, a phosphate, etc., a chelating agent such as ethylenediamine tetraacetate, diethylenetetramine pentaacetate, etc., various kinds of alcohols such as ethanol, propanol, isopropanol, ethylene glycol, diethylene glycol, triethylene glycol, glycerin, benzyl alcohol, etc. After subjecting to development treatment using the alkali developer, usual finishing treatment is preferably carried out by using Gum Arabic, dextrins, etc.

### EXAMPLES

In the following, the present invention is explained in more detail by referring to Examples, but the present invention is not limited by these Examples. Incidentally, all “%” and “part(s)” in Examples mean “% by weight” and “part(s) by weight” respectively.

<Preparation of Aluminum Support>

An aluminum plate with a thickness of 0.24 mm to which sand grinding treatment and anodization treatment have been carried out was subjected to pore sealing treatment with hot water at 90° C. for 30 seconds, and then, a conventional silicate treatment or a treatment with a solution containing potassium silicate of the present invention was carried out. The treatment conditions of the present invention and Comparative examples are shown below.

Incidentally, the No. 3 sodium silicate solution used in Comparative examples 1 to 4 is regulated by JIS-K1408 and a solution containing 28 to 30% of SiO₂ and 9 to 10% of Na₂O, and a molar ratio of SiO₂/Na₂O was 3.0 to 3.3.

An aqueous potassium silicate solution used in Comparative examples 4 and 5 and in the present invention is available from Tama Chemical Co., Ltd., Japan, and an aqueous solution containing 20% of SiO₂ and 10% of KOH. A molar ratio of SiO₂/K₂O of this aqueous solution was 3.7.

### Comparative Example 1

A solution in which water had been added to 25 parts of No. 3 sodium silicate solution to make 1000 parts in total was prepared. A molar ratio of SiO₂/Na₂O of this solution was 3.0 to 3.3.

By using this solution, the aluminum support was dipped at 70° C. for 10 seconds.

### Comparative Example 2

By using the solution of Comparative example 1, the aluminum support was dipped at 30° C. for 20 seconds.

### Comparative Example 3

NaOH was further added to the solution prepared in Comparative example 1 and a molar ratio of SiO₂/Na₂O of the solution was adjusted to about 1.6.

By using the solution, the aluminum support was dipped at 70° C. for 10 seconds.

### Comparative Example 4

By using the solution of Comparative example 3, the aluminum support was dipped at 30° C. for 20 seconds.

### Comparative Example 5

A solution in which water had been added to 100 parts of an aqueous potassium silicate solution to make 1000 parts in total was prepared. A molar ratio of SiO₂/K₂O of this solution was 3.7.

By using the solution, the aluminum support was dipped at 50° C. for 10 seconds.

### Comparative Example 6

To 50 parts of an aqueous potassium silicate solution was added 75 parts of KOH, and a total amount thereof was made 1000 parts by adding water to prepare a solution. A molar ratio of SiO₂/K₂O of this solution was 0.23.

By using the solution, the aluminum support was dipped at 30° C. for 20 seconds.

### Example 1

To 100 parts of an aqueous potassium silicate solution was added 50 parts of KOH, and a total amount thereof was made 1000 parts by adding water to prepare a solution. A molar ratio of SiO₂/K₂O of this solution was 0.62.

By using the solution, the aluminum support was dipped at 30° C. for 20 seconds.

### Example 2

To 100 parts of an aqueous potassium silicate solution was added 20 parts of KOH, and a total amount thereof was made 1000 parts by adding water to prepare a solution. A molar ratio of SiO₂/K₂O of this solution was 1.25.

By using the solution, the aluminum support was dipped at 30° C. for 20 seconds.

### Example 3

By using the solution of Example 2, the aluminum support was dipped at 50° C. for 10 seconds.

### Example 4

To 50 parts of an aqueous potassium silicate solution was added 10 parts of KOH, and a total amount thereof was made 1000 parts by adding water to prepare a solution. A molar ratio of SiO₂/K₂O of this solution was 1.25.

By using the solution, the aluminum support was dipped at 30° C. for 20 seconds.

### Example 5

By using the solution of Example 2, the aluminum support was dipped at 50° C. for 10 seconds.

### Example 6

To 150 parts of an aqueous potassium silicate solution was added 20 parts of KOH, and a total amount thereof was made 1000 parts by adding water to prepare a solution. A molar ratio of SiO₂/K₂O of this solution was 1.6.

By using the solution, the aluminum support was dipped at 30° C. for 20 seconds.

### Example 7

By using the solution of Example 6, the aluminum support was dipped at 50° C. for 10 seconds.

### Example 8

To 150 parts of an aqueous potassium silicate solution was added 13 parts of KOH, and a total amount thereof was made 1000 parts by adding water to prepare a solution. A molar ratio of SiO₂/K₂O of this solution was 2.0.

By using the solution, the aluminum support was dipped at 30° C. for 20 seconds.

### Example 9

By using the solution of Example 8, the aluminum support was dipped at 50° C. for 10 seconds.

### Example 10

To 150 parts of an aqueous potassium silicate solution was added 5 parts of KOH, and a total amount thereof was made 1000 parts by adding water to prepare a solution. A molar ratio of SiO₂/K₂O of this solution was 2.8.

By using the solution, the aluminum support was dipped at 30° C. for 20 seconds.

### Example 11

By using the solution of Example 10, the aluminum support was dipped at 50° C. for 10 seconds.

<Preparation of Negative Type Light-Sensitive Lithographic Printing Plate Material for Near Infrared Laser>

On the respective aluminum supports obtained as mentioned above, a coating solution for forming a light-sensitive layer mentioned below was so coated that a dried film thickness of 2.2 μm, and dried in a drying oven at 75° C. to obtain lithographic printing plate materials of the present invention and comparative examples.

<Coating solution for light-sensitive layer>

| | | |
|---|---|---|
| Polymer (P-1; weight average molecular weight: about | 10 | parts |
| 90,000) | | |
| Ethylenically unsaturated compound (C-5) | 2 | parts |
| Urethane compound (U-11) | 4 | parts |
| Photopolymerization initiator 1 (BC-6) | 2 | parts |
| Photopolymerization initiator 2 (T-4) | 1 | part |
| Sensitizing dye (S-39) | 0.4 | part |
| 10% Phthalocyanine dispersion | 0.5 | part |
| Dioxane | 70 | parts |
| Cyclohexanone | 20 | parts |

The lithographic printing plate materials prepared as mentioned above were each subjected to exposure by using an output machine for thermal, Imagesetter PT-R4000 (trade name) manufactured by Dainippon Screen MFG Co., Ltd. (oscillation wavelength: 830 nm, Output power: 100 mW) and treated a developer having the following prescription at 28° for 20 seconds, and successively the gum liquid having the following prescription was coated thereon.

<Developer>

| | |
|---|---|
| N-ethylethanolamine | 37 g |
| Phosphorus acid (85% solution) | 10 g |
| Tetramethylamminium hydroxide | 60 g |
| (25% solution) | |
| Sodium alkylnathalenesulfonate | 30 g |
| (35% solution) | |
| Diethylenetriaminepentaacetic acid | 1 g |
| Made up to 1 liter with water | |
| and a pH was adjusted | |
| to 11.3 (25° C.). | |

<Gum liquid>

| | |
|---|---|
| Monopotassium phosphate | 20 g |
| Gum Arabic | 30 g |
| Sodium dehydroacetate | 0.5 g |
| EDTA 2Na (disodium ethylenediamine tetraacetate) | 1 g |
| Made up to 1 liter with water. | |

The printing plates prepared as mentioned above were subjected to printing tests.

<Printing Test>

As a printing machine, Business Form Offset Rotary Printing Machine (manufactured by Miyakoshi K.K., Japan) was used. Also, UV ink (Bestcure UV RNC scarlet, trade name, available from T&K TOKA Co., Japan) and a dampening solution (5% isopropyl alcohol) were used and printing was carried out. Evaluation was carried out with a number of printed sheets when omission or disappearance of an image with regard to the solid image, 5% dots and fine line were generated.

As a result of the above-mentioned test, the lithographic printing plates using aluminum supports of Comparative examples 1 to 6 caused omission or disappearance of an image with regard to all the solid image, dots and fine line with a number of printing sheets of 10,000. On the other hand, in the lithographic printing plates using aluminum supports of Examples 2 to 9, no omission or disappearance of an image with regard to all the solid image, dots and fine line generated with a number of printing sheets of 100,000. In the lithographic printing plates using aluminum supports of Examples 1, 10 and 11, omission or disappearance of dots generated with 70,000 sheets but no omission or disappearance of an image with regard to the solid image and fine line image generated with a number of printing sheets of 100,000. Moreover, in the lithographic printing plates of the present invention, no background stain at a non-image portion generated.

1. A process for preparing a negative type light-sensitive lithographic printing plate having an aluminum plate as a support and a light-sensitive layer, provided on the support, containing a polymer, an ethylenically unsaturated compound, a photopolymerization initiator and a sensitizer having an absorption at a wavelength region of from visible light to infrared rays, which comprises subjecting the aluminum support after anodization treatment to a treatment in a solution containing potassium silicate and having a molar ratio of SiO₂/M₂O where M represents an alkali metal being in the range of 0.3 to 3.5.

2. The process for preparing a negative type light-sensitive lithographic printing plate according to claim 1, wherein the molar ratio of SiO₂/M₂O is 0.5 to 3.0.

3. The process for preparing a negative type light-sensitive lithographic printing plate according to claim 1, wherein the molar ratio of SiO₂/M₂O is 0.8 to 2.5.

4. The process for preparing a negative type light-sensitive lithographic printing plate according to claim 1, wherein the alkali metal is potassium in an amount of 50 mol % or more.

5. The process for preparing a negative type light-sensitive lithographic printing plate according to claim 1, wherein the aluminum support has been subjected to pore-sealing treatment by vapor or hot water at a temperature of 60° C. or higher after anodization and before the treatment with the solution containing potassium silicate.

6. The process for preparing a negative type light-sensitive lithographic printing plate according to claim 1, wherein the solution containing potassium silicate is treated at a temperature of lower than 70° C.

7. The process for preparing a negative type light-sensitive lithographic printing plate according to claim 1, wherein the polymer is a polymer having a polymerizable unsaturated double bond at a side chain thereof.

8. The process for preparing a negative type light-sensitive lithographic printing plate according to claim 1, wherein the polymer is a polymer containing a monomer which has a polymerizable unsaturated double bond at a side chain thereof and a carboxyl group as a copolymer component.

9. The process for preparing a negative type light-sensitive lithographic printing plate according to claim 1, wherein the ethylenically unsaturated compound is a monomer or an oligomer having two or more ethylenically unsaturated double bond in the molecule.

10. The process for preparing a negative type light-sensitive lithographic printing plate according to claim 1, wherein the polymerization initiator is an organic borate.

11. The process for preparing a negative type light-sensitive lithographic printing plate according to claim 1, wherein the sensitizer is a sensitizing dye having an absorption at near infrared rays of 750 nm or more.

12. The process for preparing a negative type light-sensitive lithographic printing plate according to claim 1, wherein the light-sensitive layer further contains a compound having an urethane bond and an ethylenically unsaturated double bond.

13. A developing method of a negative type light-sensitive lithographic printing plate, which comprises subjecting the lithographic printing plate according to claim 1 after image exposure with laser beam to development with an aqueous developer having a pH of 10 to 12.
